(19) United States
(12) Patent Application Publication
(10) Pub. No.: US 2013/0291377 A1
(43) Pub. Date: Nov. 7, 2013

(54) PANEL CARRYING VACUUM HOLDER

(71) Applicants: Kosei TANAHASHI, Asan-si (KR); Jun-Seok LEE, Cheonan-si (KR)

(72) Inventors: Kosei TANAHASHI, Asan-si (KR); Jun-Seok LEE, Cheonan-si (KR)

(73) Assignee: SAMSUNG DISPLAY CO., LTD., Yongin-City (KR)

(21) Appl. No.: 13/615,944

(22) Filed: Sep. 14, 2012

(30) Foreign Application Priority Data
May 7, 2012 (KR) 10-2012-0047950

(51) Int. Cl. H05K 13/04

(52) U.S. Cl. 29/714; 29/743

(57) ABSTRACT

A panel carrying vacuum holder includes an attachment part, a frame supporting the attachment part, and a printed circuit board (“PCB”) holder. The attachment part is configured to attach to the panel to fix the panel. The board holder includes a supporting part connected to the frame, and a pressing part. The supporting part supports a PCB connected to the panel. The pressing part is configured to press the PCB and to fix the PCB.

This application claims priority to Korean Patent Application No. 10-2012-0047950, filed on May 7, 2012, and all the benefits accruing therefrom under 35 U.S.C. §119, the contents of which are incorporated by reference herein in their entireties.

### BACKGROUND

1. Field

Exemplary embodiments of the invention relate to a panel carrying vacuum holder. More particularly, exemplary embodiments of the invention relate to a panel carrying vacuum holder to carry a display panel.

2. Description of the Related Art

A liquid display apparatus having a light weight and a small size has been manufactured. A cathode ray tube (“CRT”) display apparatus has been used due to a performance and a competitive price thereof. However the CRT display apparatus has a weakness with a size or portability. Therefore the liquid display apparatus has been highly regarded due to the small size, the light weight and low-power-consumption of the liquid display apparatus.

Generally, the liquid display apparatus applies a voltage to a specific molecular arrangement to change the molecular arrangement. The liquid display apparatus displays an image using changes in an optical property (for example, birefringence, rotatory polarization, dichroism and light scattering) of a liquid crystal cell according to the changes of the molecular arrangement.

In a manufacturing process of a display apparatus, a jig for carrying a display panel of the display apparatus may be necessary to assemble the display apparatus. However, while the display panel is carried, a flexible printed circuit board which is connected to the display panel, may be damaged.

### SUMMARY

Exemplary embodiments of the invention provide a panel carrying vacuum holder.

According to an exemplary embodiment of the invention, a panel carrying vacuum holder includes an attachment part, a frame supporting the attachment part, and a printed circuit board (“PCB”) holder. The attachment part is configured to attach to the panel and to fix the panel. The board holder includes a supporting part connected to the frame and a pressing part. The supporting part supports a PCB connected to the panel, and the pressing part is configured to press the PCB and to fix the PCB.

In an exemplary embodiment, the pressing part may press the PCB and the attachment part may be attached to the panel at a same time.

In an exemplary embodiment, the panel carrying vacuum holder may further include a lever connected to the pressing part. The lever may be activated with the attachment part being attached to the panel, so that the pressing part presses the PCB.

In an exemplary embodiment, the pressing part may include a hole. The lever may include a body, a contacting part and a pressure controlling spring. The contacting part may contact the panel. The body may extend from the contacting part and be inserted into the hole of the pressing part. The pressure controlling spring may be disposed between the pressing part and the contacting part.

In an exemplary embodiment, the board holder may further include a return spring. The return spring may apply an elasticity force to the pressing part in a direction away from the supporting part.

In an exemplary embodiment, the pressing part may pivot or rotate with respect to a rotating axis, to press the PCB. A direction of the elasticity force of the return spring may be opposite to that of the pressure controlling spring with respect to the rotating axis.

In an exemplary embodiment, the lever may include a sensor part and a driving part. The sensor part may sense whether the attachment part is attached to the panel. The driving part may move the pressing part to press the PCB when the attachment part is attached to the panel.

In an exemplary embodiment, the sensor part may include a light sensor and the driving part may include a servo-motor. The sensor part measures a distance between the panel and the board holder. The driving part moves the pressing part to press the PCB when the distance is in a predetermined range.

In an exemplary embodiment, the sensor part may include a pressure sensor and a driving part may include a servo-motor. The sensor part may contact the panel and measures a pressure between the panel and the sensor part. The driving part may move the pressing part to press the PCB when the pressure is in a predetermined range.

In an exemplary embodiment, the supporting part may include a prop contacting the PCB. The prop may include an insulation material which can absorb shock. The pressing part may include a presser contacting the PCB. The pressing part may include an insulation material which can absorb shock.

In an exemplary embodiment, the prop and the presser may include rubber. The prop may have an L-shape in a cross-sectional view.

In an exemplary embodiment, the prop may be U-shaped in a cross-sectional view. The prop may include a hole extended through an upper portion thereof. The presser may extend through the hole of the prop and press the PCB disposed in the prop, via the hole.

In an exemplary embodiment, the prop may have a wedge shaped edge.

In an exemplary embodiment, the frame may include a first frame extending in a first direction, a second frame spaced apart from the first frame and extending in the first direction, and third and fourth frames connecting the first frame to the second frame and extending in a second direction substantially perpendicular to the first direction. The board holder may include a left-right controlling part extending in the second direction. The left-right controlling part may be connected to the third frame and be configured to control a position of the board holder in the second direction.

In an exemplary embodiment, the board holder may further include an up-down controlling part. The up-down controlling part may be connected to the left-right controlling part and be configured to control a position of the board holder in the first direction.

In an exemplary embodiment, the board holder may further include an indicator indicating a position of the panel.

In an exemplary embodiment, the frame may include a first frame extending in a first direction, a second frame spaced apart from the first frame and extending in the first direction, and third and fourth frames connecting the first frame to the second frame and extending in a second direction substantially perpendicular to the first direction. The attachment part may include first and second suction plates disposed under the first frame, and third and fourth suction plates disposed under the second frame.

In an exemplary embodiment, the pressing part may pivot or rotate with respect to a rotating axis configured, to press the PCB.

In an exemplary embodiment, panel carrying vacuum holder may further include a lever connected to the pressing part. The lever may move the pressing part to press the PCB when the attachment part is attached to the panel. The pressing part may include a first link connected to the lever, a second link connected to the first link, and a third link connected to the second link.

In an exemplary embodiment, the pressing part may further include a plate spring connected to the third link, and a presser connected to the plate spring.

According to one or more embodiment of the invention, a panel carrying vacuum holder holds a PCB and a display panel at a same time, using a board holder, so that a flexible printed circuit board (“FPCB”) connected to the PCB may not be damaged. The PCB is connected to the display panel through the FPCB.

### BRIEF DESCRIPTION OF THE DRAWINGS

The above and other features of the invention will become more apparent by describing in detail exemplary embodiments thereof with reference to the accompanying drawings, in which:

FIG. 1 is a perspective view illustrating an exemplary embodiment of a panel carrying vacuum holder according to the invention;

FIG. 2 is a plan view illustrating the panel carrying vacuum holder of FIG. 1;

FIG. 3 is a perspective view illustrating an exemplary embodiment of a printed circuit board (“PCB”) holder of FIG. 1;

FIG. 4 is a cross-sectional view of the board holder of FIG. 3;

FIG. 5 is a cross-sectional view illustrating operation of the board holder of FIG. 3;

FIG. 6 is a perspective view illustrating an exemplary embodiment of a first frame and a suction plate of a panel carrying vacuum holder according to the invention;

FIG. 7 is an exploded perspective view illustrating the first frame and the suction plate of FIG. 6;

FIG. 8 is a cross-sectional view illustrating the first frame and the suction plate of FIG. 6 when the suction plate is attached to the panel;

FIG. 9 is a cross-sectional view illustrating the first frame and the suction plate of FIG. 6 when the suction plate is removed from the panel;

FIG. 10(a) is a cross-sectional view illustrating the first frame of FIG. 6 and FIG. 10(b) is a rear view illustrating the first frame of FIG. 6;

FIG. 11 is a side cross-sectional view illustrating an exemplary embodiment of a suction plate and a pad insert of FIG. 6;

FIG. 12(a) is a plan view illustrating an exemplary embodiment of a rod of FIG. 6 and FIG. 12(b) is a side view illustrating the rod of FIG. 6;

FIG. 13 is a side view illustrating an exemplary embodiment of a piston of FIG. 6;

FIG. 14(a) is a front view illustrating an exemplary embodiment of a guiding bar of FIG. 6 and FIG. 14(b) is a cross-sectional view illustrating the guiding bar of FIG. 6;

FIG. 15 is a front view illustrating an exemplary embodiment of a departing button of FIG. 6;

FIG. 16 is a cross-sectional view of another exemplary embodiment of a board holder of a panel carrying vacuum holder according to the invention;

FIG. 17 is a cross-sectional view of still another exemplary embodiment of a board holder of a panel carrying vacuum holder according to the invention; and

FIG. 18 is a perspective view of still another exemplary embodiment of a board holder of a panel carrying vacuum holder according to the invention.

### DETAILED DESCRIPTION

It will be understood that when an element or layer is referred to as being “on,” “connected to” or “coupled to” another element or layer, the element or layer can be directly on, connected or coupled to another element or layer or intervening elements or layers. In contrast, when an element is referred to as being “directly on,” “directly connected to” or “directly coupled to” another element or layer, there are no intervening elements or layers present. As used herein, connected may refer to elements being physically and/or electrically connected to each other. Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “under,” “above,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” or “under” relative to other elements or features would then be oriented “above” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the invention will be explained in detail with reference to the accompanying drawings.

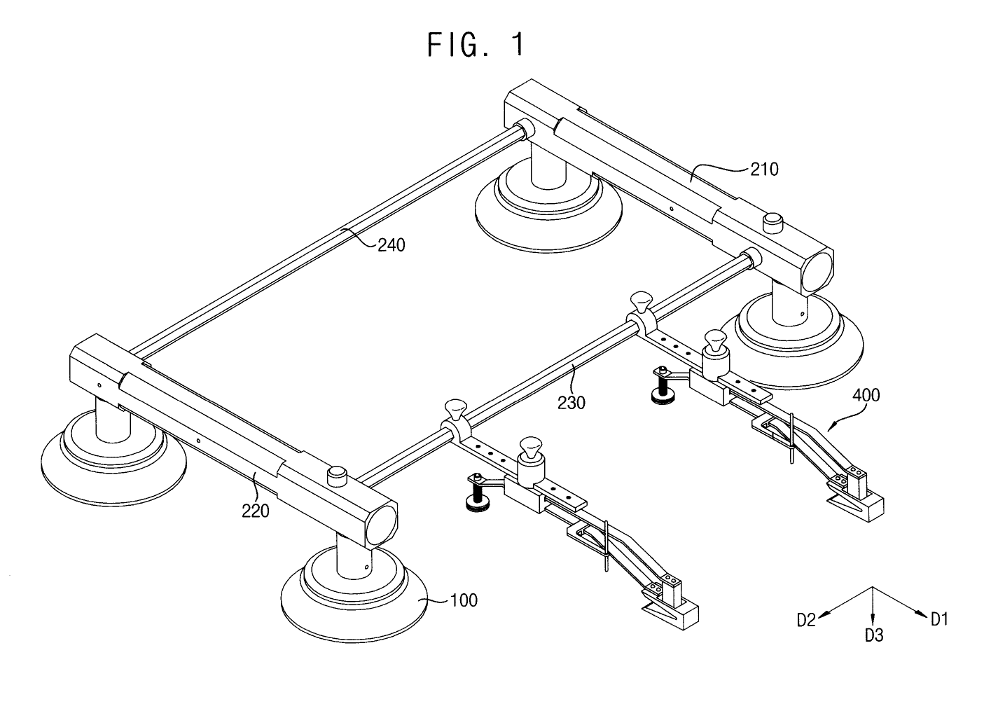

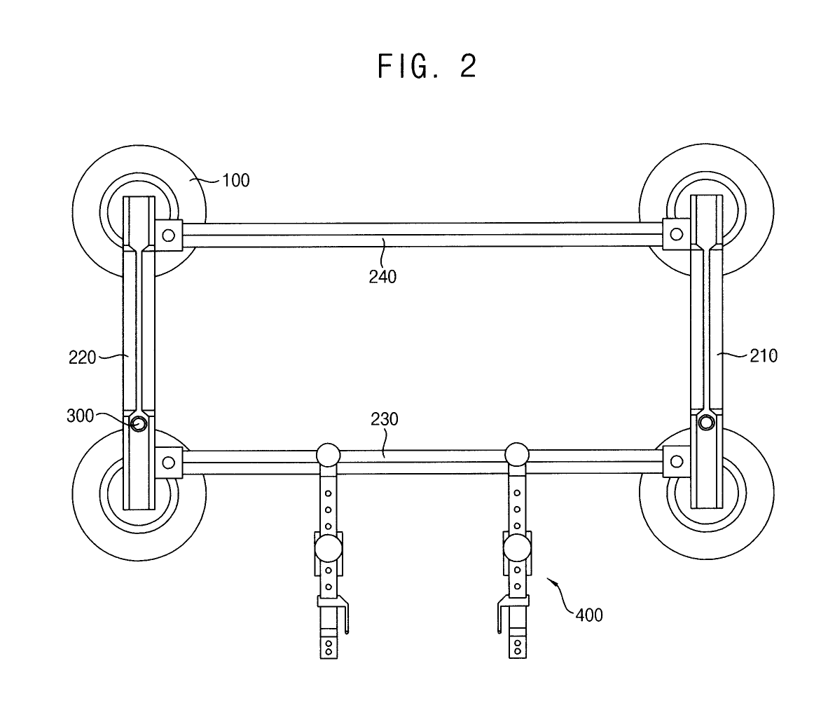

FIG. 1 is a perspective view illustrating an exemplary embodiment of a panel carrying vacuum holder according to the invention. FIG. 2 is a plan view illustrating the panel carrying vacuum holder of FIG. 1.

Referring to FIG. 1 and FIG. 2, the panel carrying vacuum holder includes an attachment part, a first frame 210, a second frame 220, a third frame 230, a fourth frame 240 and a printed circuit board (“PCB”) holder 400.

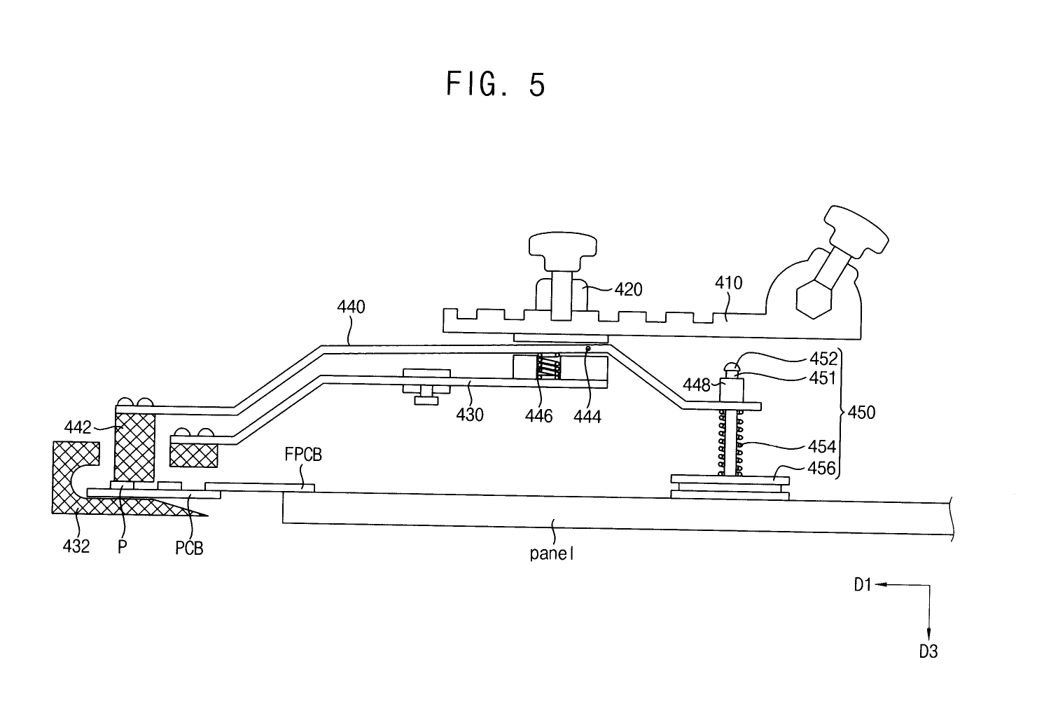

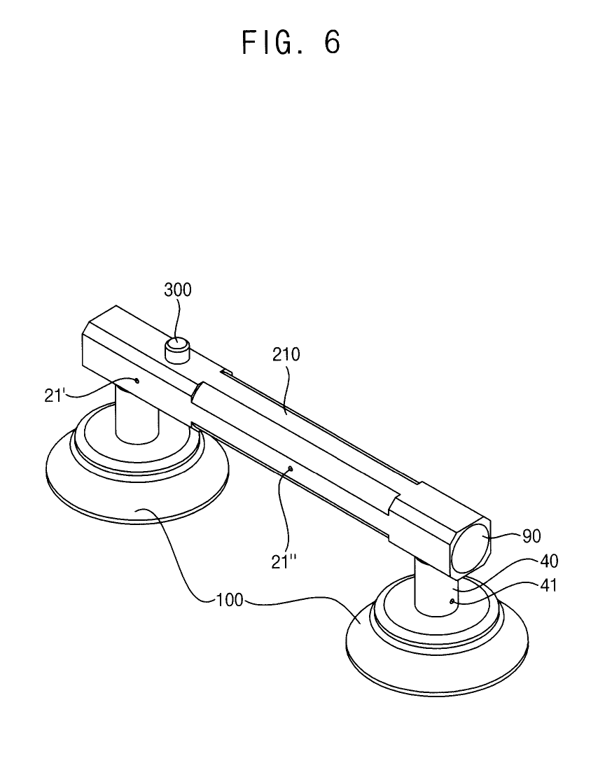

The attachment part is configured to attach to a panel (referring to the panel of FIG. 5) and fix the panel such that the panel can be carried or transported. The attachment part may include one or more of a suction plate 100 but is not limited thereto or thereby. The suction plate 100 may be a rubber pad to lift the panel using a vacuum. Detailed description about the suction plate 100 will be further provided with respect to FIGS. 6 to 15.

The first frame 210 has a longitudinal axis which extends along a first direction D1. The first frame 210 is connected to the suction plate 100, so that first frame 210 serves as a handle for a user. Detailed description will be further provided with respect to FIGS. 6 to 15.

The second frame 220 is spaced apart from the first frame 210 in a second direction D2. The second direction D2 is substantially perpendicular to the first direction D1. The second frame 220 may be substantially same as the first frame 210. Thus, any further explanation concerning the above elements will be omitted.

The third frame 230 has a longitudinal axis which extends in the second direction D2, and connects the first frame 210 to the second frame 220. The board holder 400 is disposed at the third frame 230.

The third frame 230 may have a hexagonal cross-sectional shape. The board holder 400 may be combined with the third frame 230, so that the board holder 400 may be moved in the second direction D2, but not be rotated with reference to a central axis of the third frame 230. In one exemplary embodiment, for example, the board holder 400 may include a hole employed in combination with the third frame 230.

The fourth frame 240 has a longitudinal axis which extends in the second direction D2, and connects the first frame 210 to the second frame 220. The fourth frame 240 may have a shape substantially same as the third frame 230.

The board holder 400 may be moved along the third frame 230. Thus, the board holder 400 may be moved in the second direction D2 or in an opposite direction to the second direction D2. The board holder 400 may be located at a specific position to hold a PCB connected to the panel.

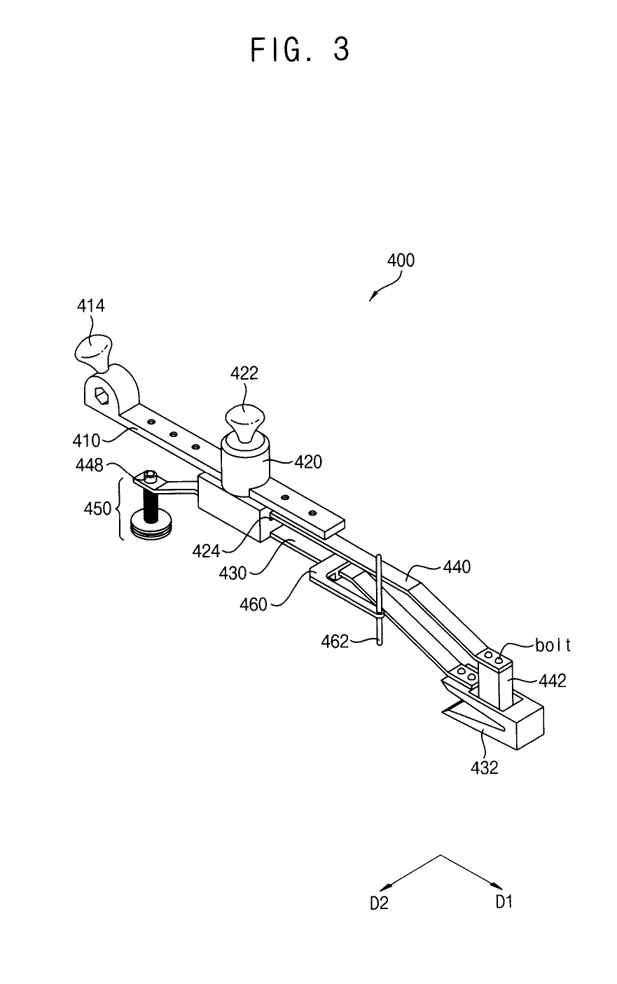

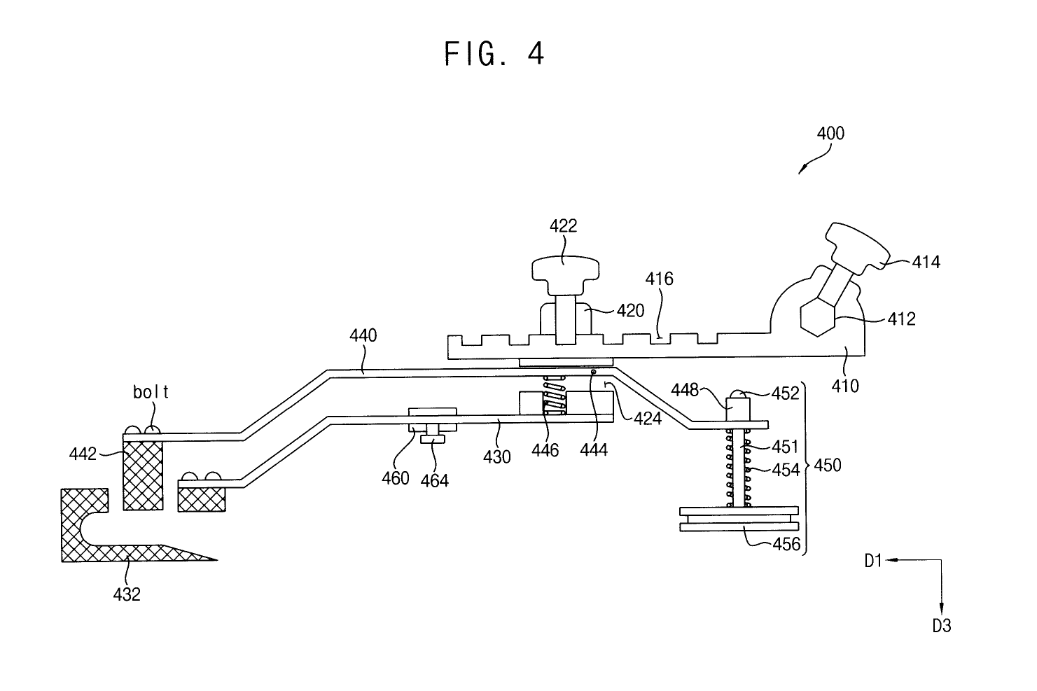

FIG. 3 is a perspective view illustrating an exemplary embodiment of a board holder of FIG. 1. FIG. 4 is a cross-sectional view of the board holder of FIG. 3.

Referring to FIGS. 3 and 4, the board holder 400 includes a left-right controlling part 410 and an up-down controlling part 420, a supporting part 430 and a pressing part 440.

The left-right controlling part 410 has a longitudinal axis which extends in the first direction D1. An end of the left-right controlling part 410 may include a portion protruded in a direction substantially orthogonal to the first and second directions D1 and D2. The left-right controlling part 410 includes a hole 412 in an end thereof, for example, in the protruded portion. The hole 412 extends substantially in the second direction D2, and has a shape corresponding to a cross-sectional shape of the third frame 230. The third frame 230 extends through the hole 412.

When a left-right controlling valve 414 is tightened, the left-right controlling part 410 may be fixed so that a position of the left-right controlling part 410 may be controlled in the second direction D2. In an exemplary embodiment, the left-right controlling valve 414 may be moveable toward and away from the hole 412, such that a distal end of the left-right controlling valve 414 is inserted in and retracted from the hole 412, or is contacted with and retracted from the third frame 230.

The left-right controlling part 410 may include a plurality of grooves 416 recessed from an upper surface thereof to control a position of the up-down controlling part 420 with respect to the left-right controlling part 410. The left-right controlling part 410 extends through the up-down controlling part 420. Thus, the position of the up-down controlling part 420 may be controlled in the first direction D1. When an up-down controlling valve 422 disposed at the up-down controlling part 420 is tightened, the up-down controlling part 420 may be fixed at the groove 416 of the left-right controlling part 410 so that a position of the up-down controlling part 420 may be controlled in the first direction D1. In an exemplary embodiment, the up-down controlling valve 422 may be moveable toward and away from a third direction D3, such that a distal end of the up-down controlling valve 422 is inserted in and retracted from the groove 416.

The supporting part 430 extends from the up-down controlling part 420 and has a longitudinal axis which extends in the first direction D1. The supporting part 430 may be connected to the third frame 230 via the up-down controlling part 420. The supporting part 430 supports the PCB of the panel, when the panel is being carried.

A prop 432 is dispose at a distal end portion of the supporting part 430. The prop 432 may be connected to supporting part 430 by a bolt but is not limited thereto or thereby. The prop 432 may include an insulation material which can absorb shock. In one exemplary embodiment, for example, the prop 432 may include rubber, but is not limited thereto or thereby. Accordingly, when the PCB of the panel is disposed on the prop 432, the PCB may not be damaged. The prop 432 may have a substantially U-shaped cross-section, so that the PCB may be disposed in the U-shaped. The prop 432 may have a wedge-shaped end or edge at an open end of the U-shaped cross-section, to lift the PCB positioned on a flat surface.

An indicator supporting part 460, an indicator 462 and a fixing pin 464 may be disposed at the supporting part 430. The indicator supporting part 460 is disposed on the supporting part 430, and may be moved along the supporting part 430 in the first direction D1. The fixing pin 464 extends through a lower thickness of the indicator supporting part 460 to press against the supporting part 430, so that the indicator supporting part 460 may be fixed to the supporting part 430. The indicator 462 is disposed at the indicator supporting part 460. The indicator 462 may have a relatively long and narrow bar shape with a longitudinal axis extending in the third direction D3 which is substantially perpendicular to the first direction D1 and the second direction D2. The indicator 462 may be located to point out a proper position according to a size of the panel and a size and location of the PCB. In one exemplary embodiment, for example, the panel carrying vacuum holder may be located at a position where the indicator 462 corresponds to a side of the panel.

The pressing part 440 has a longitudinal axis which extends in first direction D1. The pressing part 440 may be connected to the up-down controlling part 420 at a rotating axis 444. The pressing part 440 is rotatable or pivotable with reference to the rotating axis 444 in the up-down controlling part 420. Thus, the pressing part 440 rotates with reference to the rotating axis 444, so that the supporting part 430 and the pressing part 440 presses the PCB to fix the PCB of the panel in the board holder 400.

A presser 442 is disposed at a distal end of the pressing part 440. The presser 442 may be connected to the pressing part 440 by a bolt but is not limited thereto or thereby. According to the pressing part 440 being rotated, the presser 442 presses against the PCB which is disposed in the prop 432. The presser 442 extends through a hole extending through at upper portion of the prop 432, to press against the PCB. The presser 442 may be moveable toward and away from a third direction D3, such that a distal end of presser 442 is inserted in and retracted from the hole, and is contacted with and retracted from the PCB in the prop 432.

The presser 442 may include an insulation material which can absorb shock. In one exemplary embodiment, for example, the presser 442 may include rubber but is not limited thereto or thereby. Accordingly, when the PCB of the panel is pressed against the presser 442, the PCB may not be damaged. The pressing part 440 has an elasticity force in a direction opposite to a direction in which the PCB is pressed by a return spring 446 contacting the pressing part 440. Where the presser 442 is moved in the third direction D3 to press against the PCB in the prop 432, the pressing part 440 has a restoring force biased in a direction opposite to the third direction D3. Thus, the pressing part 440 may return to an original position after the panel has been carried to a desired location, so that the PCB may be removed from the prop 432.

A lever 450 is disposed at a portion of the pressing part 440 which is opposite to the presser 442 with reference to the rotating axis 444. A hitching part 448 having a passing-through-hole may be at the lever 450.

The lever 450 includes a body 451, a head 452, a pressure controlling spring 454 and a contacting part 456. The body 451 has a longitudinal axis which extends in the third direction D3 and through the hitching part 448. The head 452 is connected to a first end of the body 451, and has a diameter larger than that of the passing-through-hole of the hitching part 448, so that the head 452 cannot pass through the hitching part 448. The contacting part 456 is disposed at an opposite second end of the body 451. The contacting part 456 makes contact with a surface of the panel, when the panel is carried using the board holder 400. The contacting part 456 may include an insulation material which can absorb shock. In one exemplary embodiment, for example, the contacting part 456 may include rubber but is not limited thereto or thereby. Thus, the panel may not be damaged although the contacting part 456 presses against the panel. The pressure controlling spring 454 is disposed between the contacting part 456 and the pressing part 440. Thus, overpressing or applying excessive pressure to the panel is reduced or effectively prevented by the contacting part 456. A mechanism and operation of the lever 450 will be later described with respect to FIG. 5.

FIG. 5 is a cross-sectional view illustrating operation of the board holder of FIG. 3.

The panel may include a flexible printed circuit board (“FPCB”) attached to the panel. A first end of the FPCB is coupled to the panel and an opposite second end of the FPCB is coupled to a PCB, such that the PCB is attached to the panel via the FPCB. Relative to the panel carrying vacuum holder, the panel may be positioned such that the FPCB and PCB correspond to the prop 432.

Referring to FIG. 5, the suction plate (refer to 100 in FIG. 1) attaches to the panel, and then the presser 442 of the pressing part 440 contacts the panel and presses against the panel. The contacting portion 456 of the lever 450 may be on substantially a same plane as the opening of the prop 432, but is not limited thereto or thereby. The prop 432 is positioned to receive or support the FPCB and/or the PCB of the panel. In one exemplary embodiment, the prop 432 may be on substantially a same plane as the FPCB and/or the PCB when the panel is attached to the suction plate 100. When the suction plate 100 attaches to the panel, the panel may contact the contacting portion 456 of the lever 456. Accordingly, the pressure controlling spring 454 of the lever 450 is compressed in an opposite direction to the third direction D3, so that the pressing part 440 is rotated with reference with the rotating axis 444 by an elasticity force of the pressure controlling spring 454. The rotating of the pressing part 440 presses the presser 442 against the panel, e.g., an upper surface of the PCB, and fixes the PCB in the prop 432 connected to the supporting part 430. A lower surface of the PCB may contact the prop 432. The PCB is fixed in the board holder 400 at the same time that the suction plate (refer to 100 in FIG. 1) is attached to the panel. Thus, a FPCB connected to the PCB and the panel may be protected while the panel is carried using the panel carrying vacuum holder.

In addition, the pressure controlling spring 454 controls pressing pressure of the pressing part 440 against the PCB, so that the PCB may not be damaged. Since the presser 442 includes an insulation material which can absorb shock, a circuit pattern P disposed on the PCB may not be damaged.

The indicator 462 (refer 462 in FIG. 3) is used for adjusting a position of the panel carrying vacuum holder to locate the PCB on the prop 432. In one exemplary embodiment, for example, the indicator 462 (refer 462 in FIG. 3) may be located to indicate where the panel and the FPCB are connected each other. When the panel carrying vacuum holder attaches to the panel, the indicator 462 (refer 462 in FIG. 3) may be located to indicate where the panel and the FPCB are connected each other, so that the PCB may be appropriately located on the prop 432.

The PCB is fixed in the prop 432 by the presser 442 at the same time that the panel carrying vacuum holder is attached to the panel. The presser 442 fixes the PCB without damaging the circuit pattern P. Thus, the FPCB connected to the PCB and the panel may be protected while the panel is carried. The FPCB may include a chip on flexible printed circuit board (“COF”) but is not limited thereto or thereby.

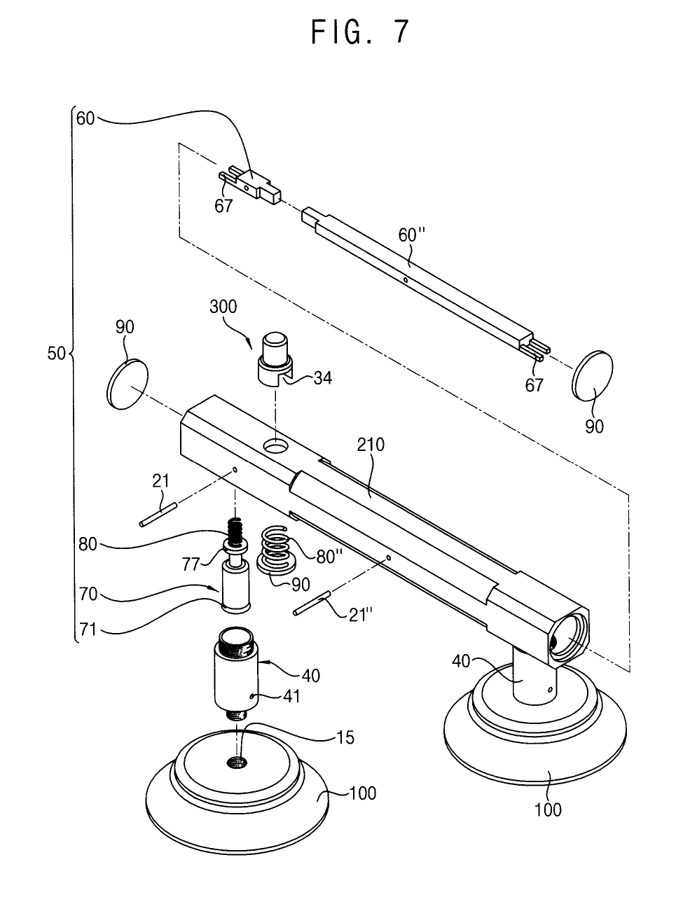

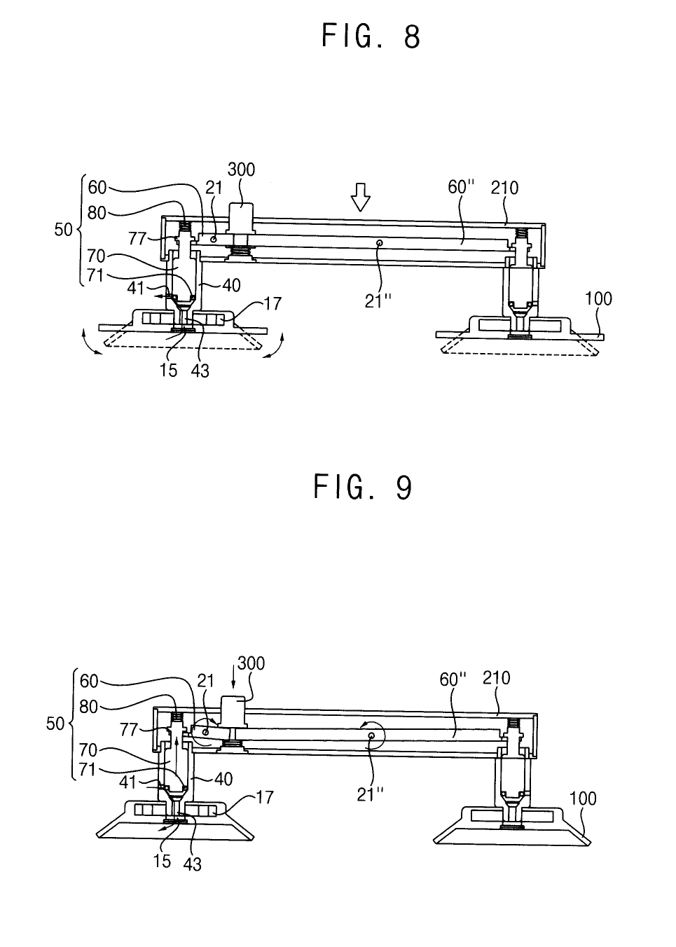

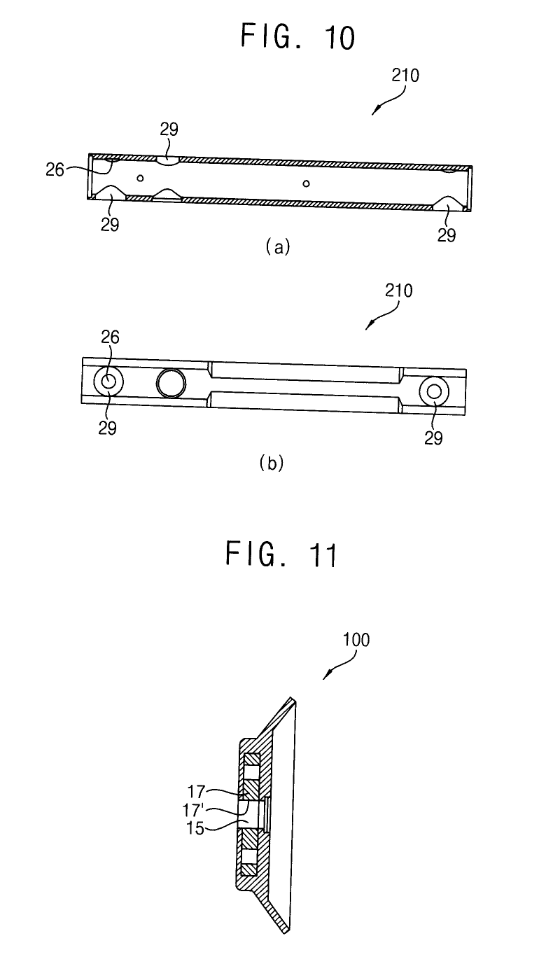

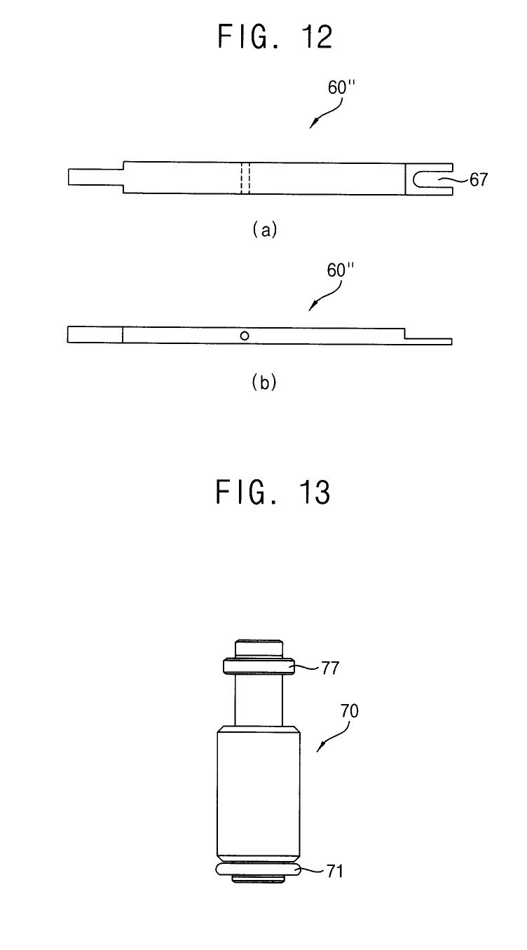

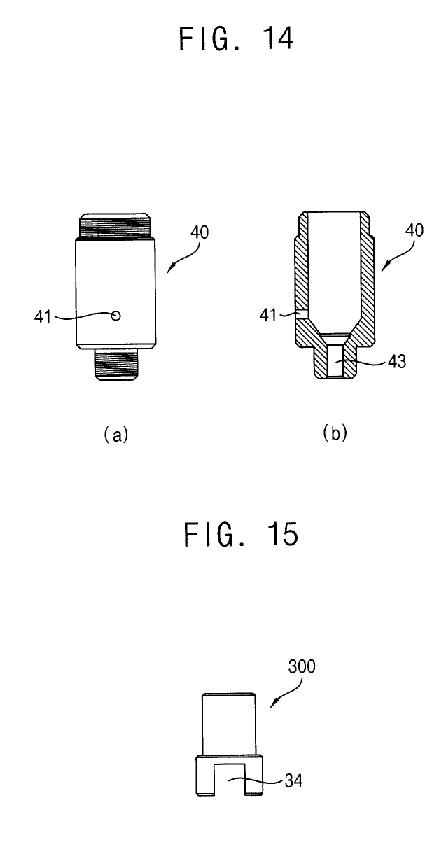

FIG. 6 is a perspective view illustrating an exemplary embodiment of a first frame and a suction plate of a panel carrying vacuum holder according to the invention. FIG. 7 is an exploded perspective view of the first frame and the suction plate of FIG. 6. FIG. 8 is a cross-sectional view illustrating the first frame and the suction plate of FIG. 6 when the suction plate is attached to the panel. FIG. 9 is a cross-sectional view illustrating the first frame and the suction plate of FIG. 6 when the suction plate is removed from the panel. FIG. 10(a) is a cross-sectional view illustrating the first frame of FIG. 6 and FIG. 10(b) is a rear view illustrating the first frame of FIG. 6. FIG. 11 is a side cross-sectional view illustrating an exemplary embodiment of a suction plate and a pad insert of FIG. 6. FIG. 12(a) is a plan view illustrating an exemplary embodiment of rods of FIG. 6 and FIG. 12(b) is a side view illustrating the rods of FIG. 6. FIG. 13 is a side view illustrating an exemplary embodiment of a piston of FIG. 6. FIG. 14(a) is a front view illustrating an exemplary embodiment of a guiding bar of FIG. 6 and FIG. 14(b) is a cross-sectional view illustrating the guiding bar of FIG. 6. FIG. 15 is a front view illustrating an exemplary embodiment of a departing button of FIG. 6.

Referring to FIGS. 6 to 15, the first frame 210 and the suction plate 100 will be described hereinafter.

The first frame 210 includes an air hole 41, two guiding bars 40 each including a through hole 43, a departing button 300 and a vacuum relieving mean 50. The vacuum relieving mean 50 is connected to the departing button 300, so that the vacuum relieving mean 50 opens the through hole 43 by depressing the departing button 300. The first frame 210 has a hollow structure. The guiding bars 40 are spaced apart each other and are disposed at opposing ends of the first frame 210. The air hole 41 is at a side of the guiding bar 40. The through hole 43 is under the guiding bar 40. The suction plate 100 is disposed under the guiding bar 40, and has an air vent 15 connected to the through hole 43. The departing button 300 is on the first frame 210.

A method of using the panel carrying vacuum holder may include a user guiding the panel carrying vacuum holder such as by holding the first frame 210 by a hand, and then press the panel carrying vacuum holder against the panel, so that a vacuum is formed between the suction plate 100 and the panel. The panel is attached to the suction plate 100 and is moveable with the panel carrying vacuum holder, so that the user may carry the panel using the panel carrying vacuum holder. After carrying the panel, the user depresses the departing button 300, such that air may be inserted into a space between the suction plate 100 and the panel, thereby detaching the suction plate 100 from the panel.

The suction plate 100 includes a pad insert 17 which is a relatively hard or rigid member. The pad insert 17 includes the air vent 15 having a tap 17′, so that the guiding bar 40 is combined to the suction plate 100 by a fastening member, such as a screw. (refer to FIG. 11)

The vacuum relieving mean 50 include two rods 60 and 60″, a piston 70, an o-ring 71 and a first spring 80. The rods 60 and 60″ are disposed in the first frame 210 such that ends thereof are movable in a hinge-like manner. A first end of the rod 60 and a first end of the rod 60″ are disposed under and/or overlapping the departing button 300. The piston 70 is disposed an opposite second end of the rod 60 or 60″ and is moveable along the guiding bar 40. The o-ring 71 surrounds the piston 70, so that the o-ring 71 may contact to or be spaced apart from an inside surface of the guiding bar 40. The first spring 80 is disposed between the piston 70 and the first frame 210.

The rods 60 and 60″ are combined to the first frame 210 by combining pins 21 and 21″ and are pivotable about an axis defined by the pins 21 and 21″, respectively. As the rods 60 and 60″ pivot about the pins 21 and 21″, the first ends of the rods 60 and 60″ may move like a hinge. When the rods 60 and 60″ move like a hinge, an angle formed between the rods 60 and 60″ changes.

Although the rods 60 and 60″ are spaced apart from and face each other with reference to the departing button 300 in the exemplary embodiment, the rods 60 and 60″ may be connected to each other to move in a hinge-like manner.

The departing button 300 is described in FIG. 15. A groove 34 having a saddle shape or an inverted U-shape is at a lower portion of the departing button 300. The rods 60 and 60″ of the vacuum-relieving means 50 may be combined to the groove 34 of the departing button 300, such that the rods may move in a hinge-like manner when the departing button 300 is depressed and released.

Referring to FIGS. 12 and 13, the rod 60 or 60″ is combined to the piston 70 by a combining groove 67 at the second end of the rod 60 or 60″. The piston 70 includes a combining protrusion 77. The combining protrusion 77 of the piston 70 is combined to the combining groove 67 of the rod 60 or 60″.

In addition, an outside surface of the piston 70 contacts the inside surface of the guiding bar 40, so that the piston 70 moves and is guided along the guiding bar 40. The inside surface of the guiding bar 40 may have a tapered shape (refer to FIG. 14), but is not limited thereto or thereby

In addition, when the o-ring 71 of the piston 70 contacts the inside surface of the guiding bar 40, the through hole 43 is closed, and the air hole 41 of the guiding bar 40 may not be fluidly connected to the air vent 15 of the suction plate 100. The o-ring 71 may contact a tapered portion of the inside surface of the guiding bar 40, or may contact both the tapered portion and an adjacent vertical wall of the inside surface, to close the through hole 43. When the o-ring 71 of the piston moves to open the through hole 43, the air hole 41 and the air vent 15 may be in fluid connection with each other and air may pass through the air hole 41.

The first spring 80 presses the piston 70 in the third direction D3, so that the o-ring 71 of the piston 80 tends to be located at an original position at which the o-ring 71 contacts the inside surface of the guiding bar 40. The first frame 210 has a portion 26 which the first spring 80 is disposed (refer to FIG. 10). The portion 26 may protrude from an inner wall of the first frame 210 such that the first spring 80 is coupled to the protruded portion 26.

In addition, the departing button 300 may have an elasticity force due to a second spring 80″ which is disposed between the departing button 300 and the first frame 210. The second spring 80″ may bias the departing button 300 in a direction opposite to the third direction D3.

In addition, a length of the rods 60 and 60″ may be different each other, so that the user may press the departing button 300 easily.

In addition, referring to FIGS. 6 and 10, the first frame 210 includes a plurality of holes 29 to install the departing button 300 and the guiding bars 40 to the first frame 210.

In addition, referring to FIG. 10, the guiding bar 40 may be connected to the first frame 210 by a fastening member, such as a screw.

In addition, to simplify manufacturing process, access covers 90 may be attached at both ends of the first frame 210, and under the second spring 80″. Since the first frame 210 is hollow, the ends of the first frame and the hole 29 receiving the second spring 80″ expose an inside of the first frame 210 to an outside of the first frame 210. When the access covers 90 are attached to the ends of the frames and the hole 29 receiving the second spring 80″, the inside of the first frame 210 is covered and not exposed to the outside of the first frame 210.

Hereinafter, referring to FIGS. 8 and 9, a mechanism of the panel carrying vacuum holder will be described.

A structure of the panel carrying vacuum holder when the suction plate 100 is attached to the panel is described in FIG. 8.

As illustrated in the figure, the suction plate 100 deforms into a flat shape, when the panel carrying vacuum holder is pressed on the panel. A dotted line shows an original position of the suction plate 100, and arrows indicate a movement direction of the edges of the suction plate between the original position and the deformed position. After the suction plate 100 deforms into a flat shape, the piston 70 moves upward from the original position, so that the o-ring 71 is separated from the inside surface of the guiding bar 40. Air between the suction plate 100 and the panel exits through the air vent 15 of the suction plate 100, the through hole 43 of the guiding bar 40 and finally through the air hole 41 of the guiding bar 40, so that a vacuum may be created between the suction plate 100 and the panel. After the vacuum is created, the piston returns to the original position, so that the o-ring 71 contacts the inside surface of the guiding bar 40 to close the through hole 43.

An arrow extending from the air vent 15 of the suction plate 100, to the through hole 43 of the guiding bar 40 and finally through the air hole 41 in the FIG. 8 represents the flow of the air between the suction plate 100 and the plate exiting through the air hole 41.

A structure of the panel carrying vacuum holder when the suction plate 100 is detached from the panel is described in FIG. 9.

As described in the figure, the departing button 300 is depressed which presses the first ends of the rods 60 and 60″ in the third direction D3. When the first ends of the rods 60 and 60″ move in the third direction D3, each of the rods 60 and 60″ moves in a hinge-like manner with respect to the combining pins 21 and 21″, so that the second ends of the rods 60 and 60″ far from the departing button 300 are lifted and moved in a direction opposite to the third direction D3.

Accordingly, the piston 70 is lifted in the direction opposite to the third direction D3, and the o-ring 71 is separated from the inside surface of the guiding bar 40, so that air from outside the guiding bar 40 inflows through the air hole 41, the through hole 43 and finally through the air vent 15.

Thus, the air inflows between the suction plate 100 and the panel, then the suction plate 100 is detached from the panel.

An arrow extending from the air hole 41, the through hole 43 and finally through the air vent 15 in FIG. 9 represents flow of the air to between the suction plate 100 and the panel.

Not shown in figures, the pad insert 17 of the suction plate 100 may be combined with the guiding bar 40 by a one-touch type of fastening member.

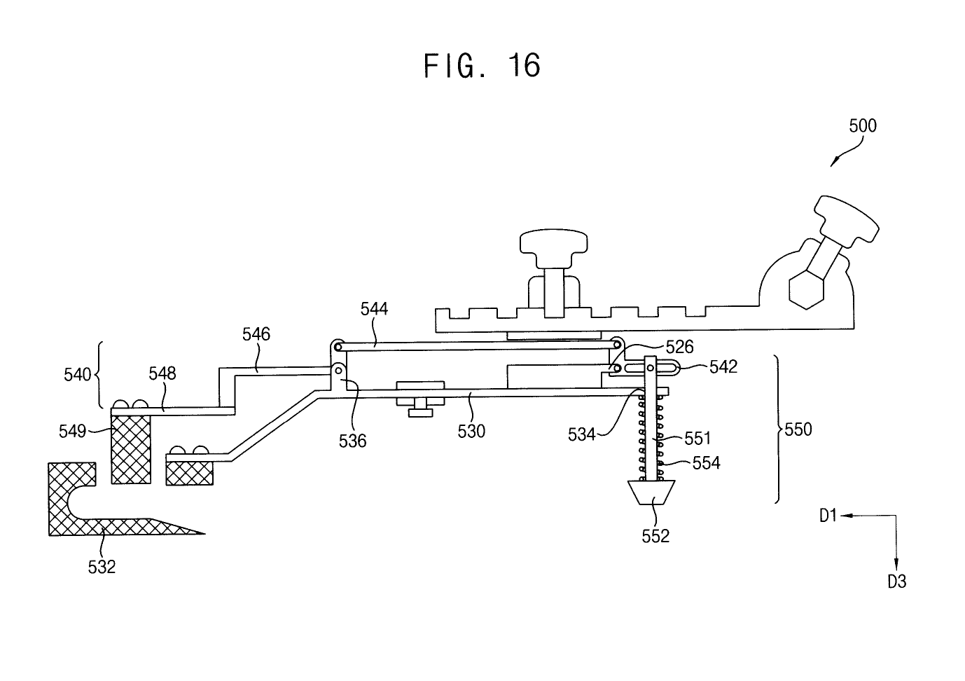

FIG. 16 is a cross-sectional view of another exemplary embodiment of a board holder of a panel carrying vacuum holder according the invention.

Referring to FIG. 16, the board holder 500 is substantially same as the board holder 400 of FIG. 3, except for a lever 550 and a pressing part 540 including a first link 542, a second link 544, a third link 546 and a plate spring 548. Thus, any further detailed descriptions concerning the same elements will be omitted.

The pressing part 540 includes the first link 542, the second link 544, the third link 546 and the plate spring 548.

The first link 542 pivotably moves with respect to a first supporting portion 526 of supporting part 530, at the up-down controlling part. The second link 544 is pivotably connected to the first link 542, and has a longitudinal axis which extends in a first direction D1. The third link 546 pivotably moves with respect to a second supporting portion 536 of the supporting part 530. The third link 546 is pivotably connected to the second link 544. The plate spring 548 is connected to the third link 546 at a distal end of the pressing part 540. A presser 549 is disposed at a distal end of the plate spring 548. The presser 549 may be connected to the plate spring 548 by a bolt, but is not limited thereto or thereby.

As the first to third links 542, 544 and 546 move, the presser 549 moves through a hole extending through a prop 532, so that the presser 549 presses against a PCB of a panel (refer to PCB of FIG. 5) disposed in the prop 532 to fix the PCB in the board holder 500. The presser 549 may include an insulation material which can absorb shock. In one exemplary embodiment, for example, the presser 549 may include rubber but is not limited thereto or thereby. Thus, the PCB may not be damaged although the presser 549 presses against the PCB of the panel.

The lever 550 includes a body 551, a contacting part 552 and a pressure controlling spring 554.

The body 551 has a longitudinal axis which extends in a third direction D3 and through a hole 534 formed through the supporting part 530. A first end of the body 551 may be pivotably connected to the first link 542 of the pressing part 540. The contacting part 552 is disposed at a second end of the body 551 opposite to the first end in the third direction D3. The contacting part 552 (refer to panel of FIG. 5) makes contact with a surface of the panel (refer to panel of FIG. 5), when the panel is carried using the board holder 500. The contacting part 552 may include an insulation material which can absorb shock. In one exemplary embodiment, for example, the contacting part 552 may include rubber but is not limited thereto or thereby. Thus, the panel may not be damaged although the contacting part 552 presses against the panel. The pressure controlling spring 554 is disposed between the contacting part 552 and the pressing part 530.

The panel carrying vacuum holder is attached to the panel (refer to panel of FIG. 5), then the contacting part 552 is pressed by the panel. Accordingly, the pressure controlling spring 554 is compressed in an opposite direction to the third direction D3 and the body 551 of the lever 550 moves in the opposite direction. In moving in the opposite direction, the body 551 lifts the first link 542 in the opposite direction. In one exemplary embodiment, for example, the body 551 and the first link 542 may be connected by a slide, so that the first link 542 may pivotably move according to up-down movement of the body 551. As the first link 542 moves in the direction opposite to the third direction D3, then the second link 544 moves in the first direction D1, then the third link 546 pivotably moves so that the presser 549 moves in the third direction D3 and presses against the PCB to fix the PCB in the prop 532.

Elasticity of the plate spring 548 may control a pressure of the presser 549 pressing the PCB. Thus, the PCB may not be damaged.

The pressing part 540 is biased in a direction opposite to a direction in which the PCB is pressed by an elasticity force of the pressure controlling spring 554. Thus, after carrying the panel, the pressing part 540 is returned to an original position, so that the PCB of the panel may be released from the prop 532.

The PCB is fixed in the prop 532 by the presser 549 at the same time that the panel carrying vacuum holder is attached to the panel. The presser 549 fixes the PCB without damaging the circuit pattern P. Thus, the FPCB connected to the PCB and the panel may be protected while the panel is carried. The FPCB may include a COF.

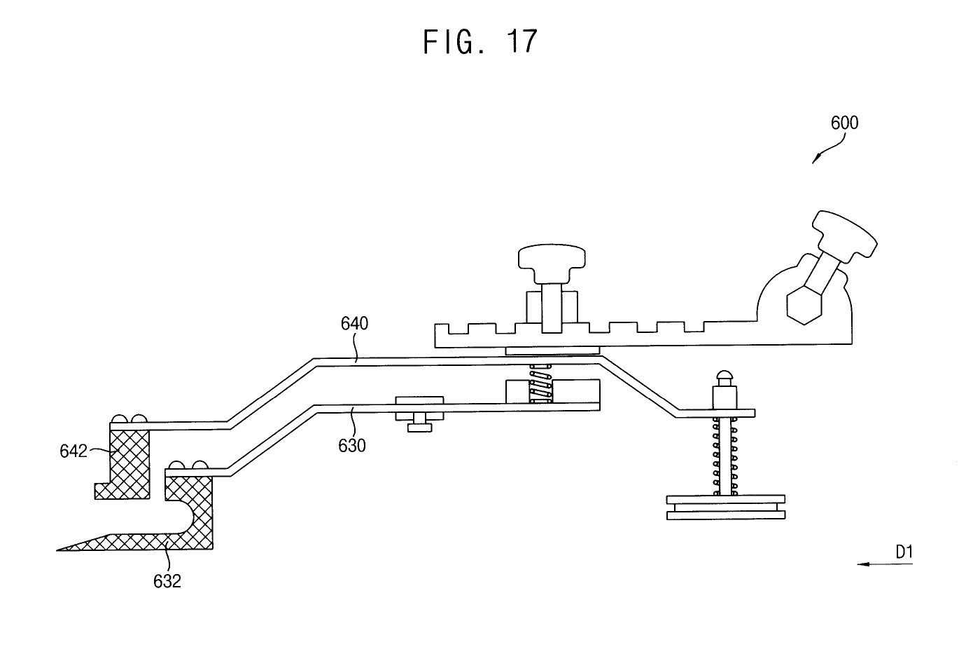

FIG. 17 is a cross-sectional view of still another exemplary embodiment of a board holder of a panel carrying vacuum holder according to the invention.

Referring to FIG. 17, the board holder 600 is substantially same as the board holder 400 of FIG. 3, except for a presser 642 and a prop 632. Thus, any further detailed descriptions concerning the same elements will be omitted.

The prop 632 is disposed at a distal end of a supporting part 630. The prop 632 may be connected to the supporting part 630 by a bolt but is not limited thereto or thereby. The prop 632 may include an insulation material which can absorb shock. In one exemplary embodiment, for example, the prop 632 may include rubber but is not limited thereto or thereby. Accordingly, when the PCB of the panel is disposed on the prop 632, the PCB may not be damaged.

The prop 632 may have an L-shaped cross-sectional view. Different from the prop in FIGS. 3 and 16, the prop 632 does not include an upper portion and a hole extended through the upper portion. The PCB of the panel may be disposed on the prop 632. The prop 632 may have a wedge-shaped end or edge at an open end of the prop 632, to lift the PCB positioned on a flat surface.

The presser 642 is disposed at a distal end of a pressing part 640 and may have an L-shaped cross-sectional view. Different from the presser in FIGS. 3 and 16, the presser 642 has a horizontal portion extending from a vertical portion. The horizontal portion may provide a larger area for the presser 642 to contact the PCB as compared to the presser in FIGS. 3 and 16. The presser 642 may be connected to the pressing part 640 by a bolt but is not limited thereto or thereby. The presser 642 may press against the PCB of the panel according to the pressing part 640 being pivoted or rotated. The presser 642 may include an insulation material which can absorb shock. In one exemplary embodiment, for example, the presser 642 may include rubber but is not limited thereto or thereby. Accordingly, when the PCB of the panel is pressed by the presser 642, the PCB may not be damaged.

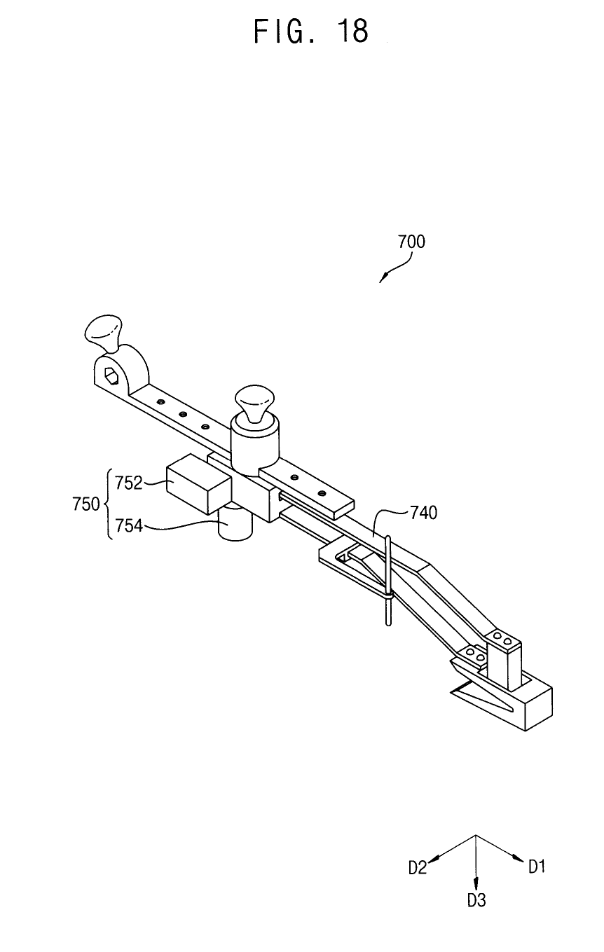

FIG. 18 is a perspective view of still another exemplary embodiment of a board holder of a panel carrying vacuum holder according to the invention.

Referring to FIG. 18, the board holder 700 is substantially same as the board holder 400 of FIG. 3, except for a lever 750 including a sensor part 754 and a driving part 752. Thus, any further detailed descriptions concerning the same elements will be omitted.

The lever 750 includes the sensor part 754 and the driving part 752. The sensor part 754 is disposed under an up-down controlling part of the board holder 700. The sensor part 754 measures a distance between the panel (refer to panel of FIG. 5) and the board holder. A predetermined distance is defined as a distance between the panel and the board holder when the panel carrying vacuum holder is attached to the panel. The driving part 752 connected to the pressing part 740 moves the pressing part 740 to press against the PCB to fix the PCB in the board holder 700 when the panel is located at a predetermined position. In one exemplary embodiment, for example, the sensor part 754 may include a light sensor to measure the distance between the panel and the board holder 700. The driving part 752 is activated when the distance is reached at the predetermined distance. In an alternative exemplary embodiment, the sensor part 754 may include a pressure sensor to measure a pressure between the panel and the sensor part 754. The sensor part may contact the panel to measure the pressure between the panel and the sensor part 754. The driving part 752 is activated when the pressure is in a predetermined range.

The driving part 752 may include a servo-motor to move the pressing part 740 to press against and fix the PCB of the panel.

When the panel carrying vacuum holder is detached from the panel, the sensing part measures the distance between the panel and the board holder 700. If the distance is different from the predetermined distance, then the driving part 752 moves the pressing part 740 to be located in an original position. Accordingly, the PCB may be released from the board holder 700.

The foregoing is illustrative of the invention and is not to be construed as limiting thereof. Although a few exemplary embodiments of the invention have been described, those skilled in the art will readily appreciate that many modifications are possible in the exemplary embodiments without materially departing from the novel teachings and advantages of the invention. Accordingly, all such modifications are intended to be included within the scope of the invention as defined in the claims. In the claims, means-plus-function clauses are intended to cover the structures described herein as performing the recited function and not only structural equivalents but also equivalent structures. Therefore, it is to be understood that the foregoing is illustrative of the invention and is not to be construed as limited to the specific exemplary embodiments disclosed, and that modifications to the disclosed exemplary embodiments, as well as other exemplary embodiments, are intended to be included within the scope of the appended claims. The invention is defined by the following claims, with equivalents of the claims to be included therein.

What is claimed is:

1. A panel carrying vacuum holder comprising:
an attachment part configured to attach to and fix the panel;
a frame which supports the attachment part; and
a board holder comprising:
a supporting part connected to the frame, wherein the supporting part supports a printed circuit board of the panel, and
a pressing part configured to press the printed circuit board of the panel and to fix the printed circuit board in the board holder.

2. The panel carrying vacuum holder of claim 1, wherein the pressing part presses the printed circuit board of the panel and the attachment part is attached to the panel at a same time.

3. The panel carrying vacuum holder of claim 2, further comprising a lever connected to the pressing part,
wherein
the lever is activated by the attachment part attached to the panel, and
the pressing part presses the printed circuit board by the activation of the lever.

4. The panel carrying vacuum holder of claim 3, wherein
the pressing part comprises a hole; and
the lever comprises:
a body which extends through the hole of the pressing part,
a contacting part which extends from the body and contacts the panel, and
a pressure controlling spring between the pressing part and the contacting part.

5. The panel carrying vacuum holder of claim 4, wherein
the board holder further comprises a return spring between the pressing part and the supporting part, and
the return spring applies an elasticity force to the pressing part in a direction away from the supporting part.

6. The panel carrying vacuum holder of claim 5, wherein
the pressing part pivots with respect to a pivot axis, and
a direction of the elasticity force of the return spring is opposite to an elasticity force of the pressure controlling spring of the lever, with respect to the pivot axis.

7. The panel carrying vacuum holder of claim 3, wherein the lever comprises:
a sensor part which senses whether the attachment part is attached to the panel, and
a driving part which moves the pressing part such that the pressing part presses the printed circuit board of the panel, when the attachment part is attached to the panel.

8. The panel carrying vacuum holder of claim 7, wherein
the sensor part comprises a light sensor and measures a distance between the panel and the board holder, and
the driving part comprises a servo-motor and moves the pressing part such that the pressing part presses the printed circuit board of the panel, when the distance is in a predetermined range.

9. The panel carrying vacuum holder of claim 7, wherein
the sensor part comprises a pressure sensor, contacts the panel and measures a pressure between the panel and the sensor part, and
the driving part comprises a servo-motor and moves the pressing part such that the pressing part presses the printed circuit board of the panel, when the pressure is in a predetermined range.

10. The panel carrying vacuum holder of claim 1, wherein
the supporting part comprises a prop which contacts the printed circuit board of the panel, and the prop comprises an insulation material configured to absorb shock, and
the pressing part comprises a presser which contacts the printed circuit board of the panel, and the presser comprises an insulation material configured to absorb shock.

11. The panel carrying vacuum holder of claim 10, wherein
the prop and the presser comprise rubber, and
the prop is L-shaped in a cross-sectional view.

12. The panel carrying vacuum holder of claim 10, wherein
the prop is U-shaped in a cross-sectional view and comprises a hole extended through an upper portion of the prop, and
the presser extends through the hole of the prop and presses the printed circuit board of the panel when the printed circuit board is in the prop.

13. The panel carrying vacuum holder of claim 12, wherein the prop has a wedge shaped edge.

14. The panel carrying vacuum holder of claim 1, wherein
the frame comprises:
a first frame extending in a first direction,
a second frame spaced apart from the first frame and extending in the first direction, and
third and fourth frames connecting the first frame to the second frame, and each extending in a second direction substantially perpendicular to the first direction,
the board holder further comprises a left-right controlling part extending in the second direction, and
the left-right controlling part is connected to the third frame and is configured to control a position of the board holder in the second direction.

15. The panel carrying vacuum holder of claim 14, wherein
the board holder further comprises an up-down controlling part, and
the up-down controlling part is connected to the left-right controlling part and is configured to control a position of the board holder in the first direction.

16. The panel carrying vacuum holder of claim 1, wherein the board holder further comprises an indicator which indicates a position of the panel with respect to the panel carrying vacuum holder.

17. The panel carrying vacuum holder of claim 1, wherein
the frame comprises:
a first frame extending in a first direction,
a second frame spaced apart from the first frame and extending in the first direction, and
third and fourth frames connecting the first frame to the second frame, and each extending in a second direction substantially perpendicular to the first direction, and
the attachment part comprises first and second suction plates under the first frame, and third and fourth suction plates under the second frame.

18. The panel carrying vacuum holder of claim 1, wherein the pressing part pivots with respect to a pivot axis such that the pressing part presses the printed circuit board of the panel.

19. The panel carrying vacuum holder of claim 1, further comprising a lever connected to the pressing part,
wherein
the lever is activated by the attachment part attached to the panel, and the pressing part presses the printed circuit board of the panel by the activation of the lever, and
the pressing part comprises a first link connected to the lever, a second link connected to the first link, and a third link connected to the second link.

20. The panel carrying vacuum holder of claim 19, wherein the pressing part further comprises:
a plate spring connected to the third link, and
a presser connected to the plate spring, wherein the presser contacts the printed circuit board of the panel.
